(19) United States
(12) Patent Application Publication
(10) Pub. No.: US 2024/0384137 A1
(43) Pub. Date: Nov. 21, 2024

(54) ADHESIVE SHEET, ADHESIVE SHEET WITH RELEASE FILM, AND ADHESIVE SHEET FOR CONSTITUENT MEMBER OF FLEXIBLE IMAGE DISPLAY DEVICE

(71) Applicant: MITSUBISHI CHEMICAL CORPORATION, Tokyo (JP)

(72) Inventor: Masaya MINEMOTO, Tokyo (JP)

(73) Assignee: MITSUBISHI CHEMICAL CORPORATION, Tokyo (JP)

(21) Appl. No.: 18/788,813

(22) Filed: Jul. 30, 2024

Related U.S. Application Data
(63) Continuation of application No. PCT/JP2023/009981, filed on Mar. 15, 2023.

(30) Foreign Application Priority Data
Mar. 30, 2022 (JP) 2022-056418

(51) Int. Cl. C09J 7/30; C09J 11/06; C09J 133/10; H10K 59/80; H10K 77/10; H10K 102/00

(52) U.S. Cl. CPC C09J 7/30; C09J 11/06; C09J 133/10; H10K 59/8722; H10K 77/111; C09J 2203/326; C09J 2301/30; C09J 2301/416; C09J 2453/00; H10K 2102/311

(57) ABSTRACT

Provided is an adhesive sheet including an adhesive layer formed from an adhesive composition containing: a (meth)acrylic copolymer (A); a photocurable compound (B); and a photopolymerization initiator (C), wherein the (meth)acrylic copolymer (A) has: a structural unit derived from an alkyl (meth)acrylate (a1) having a linear and/or branched alkyl group having 3 to 6 carbon atoms; and a structural unit derived from a (meth)acrylate (a2) having a glass transition temperature lower than that of the alkyl (meth)acrylate (a1), the structural unit derived from the alkyl (meth)acrylate (a1) is contained by not less than 20 mass % and not greater than 60 mass %, a content mass ratio (W(a2)/W(a1)) of the structural unit derived from the (meth)acrylate (a2) relative to the structural unit derived from the alkyl (meth)acrylate (a1) is 0.3 to 3.0, and the adhesive sheet has a storage shearing elastic modulus (G′) at −20° C. of not greater than 800 kPa.

### RELATED APPLICATIONS

This application is a continuation of International Application No. PCT/JP20231009981, filed on Mar. 15, 2023, which claims priority to Japanese Patent Application No. JP 2022-056418, filed on Mar. 30, 2022, the entire contents of each of which are herein incorporated by reference.

### TECHNICAL FIELD

The present disclosure relates to an adhesive sheet, an adhesive sheet with a release film, and an adhesive sheet for a constituent member of a flexible image display device. The present disclosure more specifically relates to an adhesive sheet, an adhesive sheet with a release film, and an adhesive sheet for a constituent member of a flexible image display device that have sufficient adhesiveness and flexibleness, and excellent oil resistance.

### BACKGROUND ART

Flexible image display devices using an organic light-emitting diode (OLED) and a quantum dot (QD) have been developed and commercially used widely in recent years.

The flexible image display devices include a bendable device having an image device surface having a curved shape, a foldable device that can be repeatedly folded, a rollable device that can be wound, and a stretchable device that is stretched.

Such flexible image display devices require optical properties of course, and flexibleness, specifically high durability against folding.

For example, PTL 1 discloses alaminated film with an adhesive layer causing no risk of image disturbance displayed on a folded part after repeated folding.

PTL 2 discloses a laminate comprising: a double-sided adhesive sheet having a glass transition temperature and storage elastic modulus within predetermined ranges; and a flexible member for an image display device. The laminate does not cause folding and peeling even in a bending test closely under the practical use conditions.

A cover window member of the display screen used for the above flexible image display device is expensive, and a surface-protective film may be further laminated onto a surface of the cover window for use in scratch prevention, etc.

The surface-protective film for the display screen requires not only a surface-protective property but also high durability against folding.

When a laptop personal computer, a tablet, or a smartphone is used in recent years, skin such as a finger of a human has been often contacted with the housing or the image display screen. Since oil components such as sebum and cosmetics are typically present in addition to sweat on the skin surface, use in a long term causes the oil component, etc., to gradually permeate through, for example, an edge of a binding part between a protective panel and the housing, which may permeate to an adhesive layer of the adhesive sheet. If the oil components, etc., permeate through the adhesive layer, problems occur such that an adhesive in the adhesive sheet protrudes from an edge of an adherend or adhesiveness of the surface-protective film is deteriorated to be peeled, and thereby a demand for improvement of the oil resistance has increased.

For example, PTL 3 describes that, in an adhesive containing a hydroxy-group-containing (meth)acryl resin and an isocyanate curing agent, an acrylic resin having a specific structure and an isocyanate curing agent having a specific structure are used in combination to attempt to improve folding aptitude, fat resistance, etc.

### RELATED ART DOCUMENT

### Patent Document

PTL 1: JP-A-2020-196255
PTL 2: WO-2018/173896
PTL 3: JP-A-2020-45443

### SUMMARY

### Problems to be Solved by the Disclosure

However, the art disclosed in PTLs 1 and 2 considers durability in folding but does not consider the oil resistance.

PTL 3 investigates the oil resistance, but contains methyl acrylate (Tg: 8° C.) or methyl methacrylate (Tg: 105° C.) to increase aggregation force, an isocyanate crosslinker, etc. Thus, the adhesive has a high glass transition temperature, insufficient flexibleness, specifically flexibleness at low temperature, required in recent years, and further improvement in terms of achievement of both the flexibleness and the oil resistance has been demanded.

Accordingly, under such background, the present disclosure provides an adhesive sheet having good flexibleness and excellent oil resistance, an adhesive sheet with a release film, and an adhesive sheet for a flexible image display device.

### Means for Solving the Problems

In view of the above circumstance, the present inventors have found that the flexibleness becomes good and the oil resistance becomes excellent by setting a storage shearing elastic modulus at −20° C. of an adhesive sheet to be within a specific range, the adhesive sheet comprising an adhesive layer formed from an adhesive composition comprising: a (meth)acrylic copolymer having a structural unit derived from an alkyl (meth)acrylate having a specific alkyl group and a structural unit derived from a (meth)acrylate having a glass transition temperature lower than that of the alkyl (meth)acrylate, wherein a proportion of the structural unit derived from the alkyl (meth)acrylate and a content mass ratio of the structural unit derived from the (meth)acrylate having a glass transition temperature lower than that of the alkyl (meth)acrylate relative to the structural unit derived from the alkyl (meth)acrylate are within specific ranges; a photocurable compound; and a photopolymerization initiator.

Specifically, the present disclosure has the following aspects.
[i] An adhesive sheet, comprising an adhesive layer formed from an adhesive composition containing: a (meth)acrylic copolymer (A); a photocurable compound (B); and a photopolymerization initiator (C), wherein
   the (meth)acrylic copolymer (A) has: a structural unit derived from an alkyl (meth)acrylate (a1) having a linear and/or branched alkyl group having 3 to 6 carbon atoms; and a structural unit derived from a (meth)acrylate (a2) in which a homopolymer thereof has a glass transition temperature lower than that of the alkyl (meth)acrylate (a1),
   the structural unit derived from the alkyl (meth)acrylate (a1) is contained by not less than 20 mass % and not greater than 60 mass % relative to 100 mass % of all structural units to constitute the (meth)acrylic copolymer (A),
   a content mass ratio (W(a2)/W(a1)) of the structural unit derived from the (meth)acrylate (a2) relative to the structural unit derived from the alkyl (meth)acrylate (a1) is 0.3 to 3.0, and
   the adhesive sheet has a storage shearing elastic modulus (G′) at −20° C. of not greater than 800 kPa.
[ii] The adhesive sheet according to [i], wherein the (meth)acrylic copolymer (A) further has a structural unit derived from a polar-group-containing monomer (a3).
[iii] The adhesive sheet according to [i] or [ii], wherein the (meth)acrylic copolymer (A) has a weight-average molecular weight of 600,000 to 1,500,000.
[iv] The adhesive sheet according to any one of [i] to [iii], wherein the photocurable compound (B) is a (meth)acrylate having a polyalkylene oxide skeleton.
[v] The adhesive sheet according to any one of [i] to [iv], wherein the adhesive composition further comprises a silane coupling agent (D).
[vi] The adhesive sheet according to any one of [i] to [v], wherein the adhesive sheet has a storage shearing elastic modulus (G′) at −20° C. of not greater than 500 kPa.
[vii] The adhesive sheet according to any one of [i] to [vi], wherein the adhesive sheet has a gel fraction of 30 to 95 mass %.
[viii] The adhesive sheet according to any one of [i] to [vii], wherein the adhesive sheet has an oil-resistant adhesion rate (X) determined by the following formulaof not less than 84%,

$$X ( \% ) = ( B / A ) \times 100$$

wherein A represents an adhesive force relative to a surface of a polyimide film where the adhesive sheet is cut to 10 mm in width×150 mm in length and adheres to the polyimide film, and peeled at 23° C., 50% RH, a peeling angle of 180°, and a peeling speed of 300 mm/min., and
B represents an adhesive force relative to a surface of a polyimide film where the adhesive sheet is cut to 10 mm in width×150 mm in length and adheres to the polyimide film, a mixed liquid of Oleic acid:Squalene=1:1 (an artificial sebum liquid) is dropped at 1 μL/cm at both ends in a length direction of the adhesive sheet, the adhesive sheet is stored at 23° C. and 50% RH for five days, and then peeled at a peeling angle of 180° and a peeling speed of 300 mm/min.
[ix] The adhesive sheet according to any one of [i] to [viii], wherein the adhesive sheet is transparent.
[x] The adhesive sheet according to any one of [i] to [ix], wherein the adhesive sheet has a total light transmittance of not less than 80% and a haze of not greater than 5%.
[xi] The adhesive sheet according to any one of [i] to [ix], wherein the adhesive sheet is used for a constituent member of a flexible image display device.
[xii] An adhesive sheet with a release film, wherein the adhesive sheet has a configuration in which the adhesive sheet according to any one of [i] to [xi] and a release film are laminated.
[xiii] An adhesive sheet for a constituent member of a flexible image display device, the adhesive sheet comprising:
   the adhesive sheet according to any one of [i] to [xi]; or
   the adhesive sheet with a release film according to [xii].
[xiv] The adhesive sheet for a constituent member of a flexible image display device according to [xiii], wherein the constituent member of a flexible image display device comprises any one member selected from a polyethylene terephthalate film, a polyimide film, an aramid film, and a glass plate.

### Effects of the Disclosure

The adhesive sheet according to an embodiment of the present disclosure is the adhesive sheet for a surface-protective film having a surface-protective function, flexibleness such as bendability, softness, and recovering ability, and excellent oil resistance while the adhesive sheet adheres to, for example, a flexible image display device, for use.

### Embodiments of the Disclosure

Hereinafter, an example of embodiments of the present disclosure will be described in detail. Note that the present disclosure is not limited to embodiments described below.

In the present disclosure, “film” conceptionally encompasses sheets, films, and tapes.

The expression “panel” as used in “image display panel” and “protection panel” encompasses plates, sheets, and films.

In the present disclosure, the description “x to y,” wherein x and y are given numbers, encompasses meanings of “preferably greater than x” and “preferably less than y” unless otherwise specified, in addition to a meaning of “not less than x and not greater than y”

The description “not less than x,” wherein x is a given number, encompasses a meaning of “preferably greater than x” unless otherwise specified. The description “not greater than y,” wherein y is a given number, encompasses “preferably less than y” unless otherwise specified.

Further, the expression “x and/or y,” wherein x and y are each a given form, means at least one of x and y, and means the following three meanings: only x; only y; and x and y

In the present disclosure, “main component” means a component that significantly affects properties of an object, and a content of the component is typically not less than 30 mass %, preferably not less than 35 mass %, and more preferably not less than 50 mass % in the object.

In the present disclosure, the term “(meth)acryl” means to encompass “acryl” and “methacryl,” the term “(meth)acrylate” means to encompass “acrylate” and “methacrylate,” and the term “(meth)acryloyl” means to encompass “acryloyl” and “methacryloyl.”

### <Adhesive Composition>

The adhesive sheet according to an embodiment of the present disclosure (hereinafter, referred to as “the present sheet”) is formed from an adhesive composition containing a (meth)acrylic copolymer (A) as a main component, and further containing a photocurable compound (B) and a photopolymerization initiator (C).

The adhesive composition is preferable in terms of easy regulation of a crosslinking density and a curing degree by curing with active energy radiation, and a small damage to a substrate, etc. The adhesive composition may be a material curable in a plurality of stages, as described later.

### (Meth)acrylic Copolymer (A)

The (meth)acrylic copolymer (A) has: a structural unit derived from an alkyl (meth)acrylate (a1) having a linear and/or branched alkyl group having 3 to 6 carbon atoms; and a structural unit derived from a (meth)acrylate (a2) in which a homopolymer thereof has a glass transition temperature lower than that of the alkyl (meth)acrylate (a1).

### Alkyl (Meth)acrylate (a1)

The glass transition temperature of the homopolymer of the alkyl (meth)acrylate (a1) having a linear and/or branched alkyl group having 3 to 6 carbon atoms is typically −10 to −80° C., preferably −15 to −70° C., and particularly preferably −40 to −60° C. Setting the glass transition temperature of the alkyl (meth)acrylate (a1) to be within the above range tends to yield excellent oil resistance.

As the glass transition temperature of the homopolymer, a value described in a polymer handbook may be used, for example.

Specific examples of the alkyl (meth)acrylate (a1) having an alkyl group include: linear alkyl (meth)acrylates such as n-propyl (meth)acrylate, n-butyl (meth)acrylate, n-pentyl (meth)acrylate, and n-hexyl (meth)acrylate; branched alkyl (meth)acrylates such as s-butyl (meth)acrylate, t-butyl (meth)acrylate, isopentyl (meth)acrylate, and neopentyl (meth)acrylate; and alicyclic (meth)acrylates such as cyclohexyl (meth)acrylate. These may be contained singly or in combination in the (meth)acrylic copolymer (A) as the structural unit. Among these, the linear alkyl (meth)acrylates are preferable in terms of the oil resistance, and n-butyl (meth)acrylate is particularly preferable.

A proportion of the structural unit derived from the alkyl (meth)acrylate (a1) relative to 100 mass % of all the structural units constituting the (meth)acrylic copolymer (A) is 20 to 60 mass %, preferably 24 to 56 mass %, and particularly preferably 28 to 52 mass %. Setting the proportion of the structural unit derived from the alkyl (meth)acrylate (a1) yields excellent oil resistance.

### (Meth)acrylate (a2)

The (meth)acrylate (a2) in which a homopolymer thereof has a glass transition temperature lower than that of the alkyl (meth)acrylate (a1) is not particularly limited, and examples thereof include alkyl (meth)acrylates [excluding the alkyl (meth)acrylate (a1)], hydroxy-group-containing (meth)acrylates, amino-group-containing (meth)acrylates, isocyanate-group-containing (meth)acrylates, carboxy-group-containing (meth)acrylates, acetoacetyl-group-containing (meth)acrylates, and glycidyl-group-containing (meth)acrylates. Among these, a (meth)acrylate having a glass temperature lower than that of the alkyl (meth)acrylate (a1) is used in the present disclosure. The (meth)acrylate (a2) may be contained singly or in combination in the (meth)acrylic copolymer (A) as the structural unit.

When two or more types of the structural units derived from the alkyl (meth)acrylate (a1) are contained in the (meth)acrylic copolymer (A), the used (meth)acrylate (a2) needs to have a glass transition temperature lower than those of all the contained alkyl (meth)acrylates (a1).

Examples of the alkyl (meth)acrylate include: linear (meth)acrylates such as methyl (meth)acrylate, ethyl (meth)acrylate, n-heptyl (meth)acrylate, n-octyl (meth)acrylate, n-nonyl (meth)acrylate, n-decyl (meth)acrylate, undecyl (meth)acrylate, lauryl (meth)acrylate, tridecyl (meth)acrylate, tetradecyl (meth)acrylate, cetyl (meth)acrylate, and stearyl (meth)acrylate; branched (meth)acrylates such as 2-ethylhexyl (meth)acrylate, isooctyl (meth)acrylate, isononyl (meth)acrylate, isodecyl (meth)acrylate, and isostearyl (meth)acrylate; and alicyclic (meth)acrylates such as t-butylcyclohexyl (meth)acrylate, 3,5,5-trimethylcyclohexyl (meth)acrylate, dicyclopentanyl (meth)acrylate, dicyclopentenyl (meth)acrylate, dicyclopentenyloxyethyl (meth)acrylate, and isobornyl (meth)acrylate.

Examples of the hydroxy-group-containing (meth)acrylate include: hydroxy (meth)acrylates such as 2-hydroxyethyl (meth)acrylate, 4-hydroxybutyl (meth)acrylate, 5-hydroxypentyl (meth)acrylate, 6-hydroxyhexyl (meth)acrylate, and 8-hydroxyoctyl (meth)acrylate; caprolactone-modified hydroxy (meth)acrylates such as caprolactone-modified 2-hydroxyethyl (meth)acrylate; oxyalkylene-modified (meth)acrylates such as diethylene glycol (meth)acrylate and polyethylene glycol (meth)acrylate; primary-hydroxy-group-containing (meth)acrylates such as 2-acryloyloxyethyl-2-hydroxyethylphthalic acid; secondary-hydroxy-group-containing (meth)acrylates such as 2-hydroxypropyl (meth)acrylate, 2-hydroxybutyl (meth)acrylate, and 3-chloro-2-hydroxypropyl (meth)acrylate; and tertiary-hydroxy-group-containing (meth)acrylates such as 2,2-dimethyl-2-hydroxyethyl (meth)acrylate.

Examples of the amino-group-containing (meth)acrylates include: primary-amino-group-containing (meth)acrylates such as aminomethyl (meth)acrylate and aminoethyl (meth)acrylate; secondary-amino-group-containing (meth)acrylates such as t-butylaminoethyl (meth)acrylate and t-butylaminopropyl (meth)acrylate; tertiary-amino-group-containing (meth)acrylates such as ethylaminoethyl (meth)acrylate, dimethylaminoethyl (meth)acrylate, diethylaminoethyl (meth)acrylate, dimethylaminopropyl (meth)acrylate, diethylaminopropyl (meth)acrylate, and dimethylaminopropylacrylamide.

Examples of the isocyanate-group-containing (meth)acrylates include 2-(meth)acryloyloxyethyl isocyanate and alkylene oxide adduct thereof. The isocyanate group may be protected with a blocking agent such as methyl ethyl ketone oxime, 3,5-dimethylpyrazole, 1,2,4-triazole, and diethyl malonate.

Examples of the carboxy-group-containing (meth)acrylates include (meth)acrylic acid, carboxyethyl (meth)acrylate, 2-(meth)acryloyloxyethylhexahydrophthalic acid, 2-(meth)acryloyloxypropylhexahydrophthalic acid, 2-(meth)acryloyloxyethylphthalic acid, 2-(meth)acryloyloxypropylphthalic acid, 2-(meth)acryloyloxyethylmaleic acid, 2-(meth)acryloyloxypropylmaleic acid, 2-(meth)acryloyloxyethylsuccinic acid, and 2-(meth)acryloyloxypropylsuccinic acid.

Examples of the acetoacetyl-group-containing (meth)acrylates include 2-(acetoacetoxy)ethyl (meth)acrylate.

Examples of the glycidyl-group-containing (meth)acrylates include glycidyl (meth)acrylate and allylglycidyl (meth)acrylate.

The glass transition temperature of the homopolymer of the (meth)acrylate (a2) is typically −20 to −90° C., preferably −40 to −85° C., and particularly preferably −60 to −80° C. Setting the glass transition temperature of the (meth)acrylate (a2) to be within the above range tends to yield excellent flexibleness.

The difference between the glass transition temperature of the alkyl (meth)acrylate (a1) and that of the (meth)acrylate (a2) is typically 1 to 40° C., preferably 5 to 30° C., and particularly preferably 10 to 20° C. When a plurality of the alkyl (meth)acrylates (a1) and the (meth)acrylates (a2) are contained, a difference between the alkyl (meth)acrylate (a1) having the lowest glass transition temperature and the alkyl (meth)acrylate (a2) having the highest glass transition temperature is within the above range.

Among these, the (meth)acrylate (a2) is preferably an alkyl (meth)acrylate, and more preferably a branched alkyl (meth)acrylate in terms of flexibleness.

In a specific preferable example of the (meth)acrylic copolymer (A), the alkyl (meth)acrylate (a1) is n-butyl (meth)acrylate and the (meth)acrylate (a2) is 2-ethylhexyl (meth)acrylate.

A proportion of the structural unit derived from the (meth)acrylate (a2) relative to 100 mass % of all the structural units constituting the (meth)acrylic copolymer (A) is typically 10 to 60 mass %, preferably 14 to 50 mass %, and particularly preferably 18 to 45 mass %. Setting the proportion of the structural unit derived from the (meth)acrylate (a2) to be the above range tends to yield excellent flexibleness.

A content mass ratio [W(a2)/W(a1)] of the structural unit derived from the (meth)acrylate (a2) relative to the structural unit derived from the alkyl (meth)acrylate (a1) is 0.3 to 3.0, and preferably 0.4 to 1.5.

Setting the content mass ratio between the alkyl (meth)acrylate (a1) and the (meth)acrylate (a2) to be within the above range yields excellent flexibleness and oil resistance.

In the (meth)acrylic copolymer (A) of the present disclosure, containing the structural unit derived from the alkyl (meth)acrylate (a1) can yield high oil resistance, and containing the structural unit derived from the (meth)acrylate (a2) can yield excellent flexibleness.

Since the (meth)acrylate (a1) and the (meth)acrylate (a2) have different number of carbon atoms in the alkyl chain and the functional group structure, the compatibility tends to be insufficient, and a phase-separated structure may be generated during the polymerization to cause a defect of clouding the polymer. However, when the content mass ratio [W(a2)/W(a1)] of the structural unit derived from the (meth)acrylate (a2) relative to the structural unit derived from the alkyl (meth)acrylate (a1) is set to be within the predetermined range, the transparent adhesive sheet having both good oil resistance and flexibleness, and having optical uniformity can be obtained.

The (meth)acrylic copolymer (A) preferably further has a structural unit derived from a polar-group-containing monomer (a3). Containing the structural unit derived from the polar-group-containing monomer (a3) tends to impart aggregation force and a crosslinking acceleration effect.

Examples of the polar-group-containing monomer (a3) include hydroxy-group-containing monomer, carboxy-group-containing monomer, and nitrogen-atom-containing monomer. These may be contained singly or in combination in the (meth)acrylic copolymer (A) as the structural unit. Among these, the hydroxy-group-containing monomer and the carboxy-group-containing monomer are more preferable, and the hydroxy-group-containing monomer is further preferable in terms of excellent reactivity with a photocurable compound (B) described later.

Examples of the hydroxy-group-containing monomer include the monomers described in the hydroxy-group-containing (meth)acrylate.

Examples of the carboxy-group-containing monomer include the monomers described in the carboxy-group-containing (meth)acrylate, crotonic acid, fumaric acid, maleic acid, itaconic acid, monomethyl maleate, and monomethyl itaconate.

Examples of the nitrogen-atom-containing monomer include amino-group-containing monomer, amide-group-containing monomer, and isocyanate-group-containing monomer.

Examples of the amino-group-containing monomer include the monomers described in the amino-group-containing (meth)acrylate.

Examples of the amide-group-containing monomer include: (meth)acrylamide; N-alkyl(meth)acrylamides such as N-methyl(meth)acrylamide, N-ethyl(meth)acrylamide, N-propyl(meth)acrylamide, N-n-butyl(meth)acrylamide, diacetone (meth)acrylamide, and N,N′-methylenebis(meth)acrylamide; N,N-dialkyl(meth)acrylamides such as N,N-dimethyl(meth)acrylamide, N,N-diethyl(meth)acrylamide, N,N-dipropyl(meth)acrylamide, N,N-ethylmethyl(meth)acrylamide, and N,N-diallyl(meth)acrylamide; hydroxyalkyl(meth)acrylamides such as N-hydroxymethyl(meth)acrylamide and N-hydroxyethyl(meth)acrylamide; and alkoxyalkyl(meth)acrylamides such as N-methoxymethyl(meth)acrylamide and N-(n-butoxymethyl)(meth)acrylamide.

Examples of the isocyanate-group-containing monomer include the monomers described in the isocyanate-group-containing (meth)acrylate.

Among the structural units derived from the polar-group-containing monomer (a3), the (meth)acrylic copolymer (A) preferably has a structural unit derived from the hydroxy-group-containing monomer, more preferably has a structural unit derived from a primary-hydroxy-group-containing (meth)acrylate, and particularly preferably has a structural unit derived from 2-hydroxyethyl (meth)acrylate and/or 4-hydroxybutyl acrylate in terms of aggregation force.

A proportion of the structural unit derived from the polar-group monomer (a3) relative to 100 mass % of all the structural units constituting the (meth)acrylic copolymer (A) is typically not greater than 45 mass %, preferably 1 to 40 mass %, more preferably 5 to 37 mass %, and particularly preferably 15 to 35 mass %.

When the polar-group-containing monomer (a3) also corresponds to the (meth)acrylate (a2), such a polar-group-containing monomer (a3) is excluded from the (meth)acrylate (a2). Note that, when the structural unit derived from the (meth)acrylate (a2) contained in the (meth)acrylic copolymer (A) is only the structural unit derived from the polar-group-containing monomer (a3), the polar-group-containing monomer (a3) is regarded as the (meth)acrylate (a2).

The (meth)acrylic copolymer (A) may have a structural unit derived from: a monomer not corresponding to the (meth)acrylate (a2) among the monomers described in the aforementioned (meth)acrylate (a2); and another copolymerizable monomer (hereinafter, these monomers are collectively referred to as “other monomers”). These may be contained singly or in combination in the (meth)acrylic copolymer (A) as the structural unit.

Examples of the other copolymerizable monomers include: aromatic (meth)acrylates such as phenyl (meth)acrylate, benzyl (meth)acrylate, phenoxyethyl (meth)acrylate, phenyl diethylene glycol (meth)acrylate, phenoxy polyethylene glycol (meth)acrylate, phenoxy polyethylene glycol-polypropylene glycol (meth)acrylate, and nonylphenol ethylene-oxide-adduct (meth)acrylate; (meth)acrylates having a benzophenone structure such as 4-acryloyloxybenzophenone, 4-acryloyloxyethoxybenzophenone, 4-acryloyloxy-4′-nethoxybenzophenone, 4-acryloyloxyethoxy-4′-nethoxybenzophenone, 4-acryloyloxy-4′-bromobenzophenone, 4-acryloyloxyethoxy-4′-bromobenzophenone, 4-methacryloyloxybenzophenone, 4-nethacryloyloxyethoxybenzophenone, 4-nethacryloyloxy-4′-methoxybenzophenone, 4-nethacryloyloxyethoxy-4′-methoxybenzophenone, 4-methacryloyloxy-4′-bromobenzophenone, 4-nethacryloyloxyethoxy-4′-bromobenzophenone, and a mixture thereof; acrylonitrile, methacrylonitrile, styrene, α-methylstyrene, vinyl stearate, vinyl propionate, vinyl acetate, vinyl chloride, vinylidene chloride, alkyl vinyl ether, vinyltoluene, vinylpyridine, vinylpyrrolidone, itaconic acid dialkyl ester, fumaric acid dialkyl ester, allyl acetoacetate, allyl alcohol, acryl chloride, methyl vinyl ketone, N-acrylamidomethyltrimethylammonium chloride, allyltrimethylammonium chloride, and vinyl-group containing monomer such as dimethylallyl vinyl ketone.

A proportion of the structural unit derived from the other monomers relative to 100 mass % of all the structural units constituting the (meth)acrylic copolymer (A) is typically not greater than 30 mass %, preferably not greater than 25 mas %, and more preferably not greater than 20 mass %. The lower limit is typically 0 mass %.

The (meth)acrylic copolymer (A) is obtained by copolymerizing the alkyl (meth)acrylate (a1), the (meth)acrylate (a2), preferably the polar-group-containing monomer (a3), and the other monomers as necessary so that the proportions of the structural units are the above-described proportions. As the polymerization method, conventionally known polymerization methods such as, for example, solution polymerization, suspension polymerization, bulk polymerization, and emulsion polymerization may be used, but manufacture by the solution polymerization is preferable in terms of safe and stable manufacture of the (meth)acrylic copolymer (A) at any proportion of the structural units.

Into the (meth)acrylic copolymer (A), a photoactive moiety, for example, a polymerizable carbon double bond group, may be introduced at the side chain. This can improve crosslinking efficiency of the adhesive composition, and the adhesive composition is crosslinked by irradiation with active energy radiation for a shorter time to improve productivity.

Examples of the method for introducing the polymerizable carbon double bond group at the side chain of the (meth)acrylic copolymer (A) include amethod of manufacturing the (meth)acrylic copolymer (A) having the structural units derived from the aforementioned polar-group-containing monomer (a3) or glycidyl-group-containing (meth)acrylate, and then performing a condensation or addition reaction of a compound having a functional group that can reac with these functional groups and the polymerizable carbon double bond group while keeping the activity of the polymerizable carbon double bond group.

Examples of combination of these functional groups include epoxy group (glycidyl group) and carboxyl group, amino group and carboxy group, amino group and isocyanate group, epoxy group (glycidyl group) and amino group, hydroxy group and epoxy group, and hydroxy group and isocyanate group. Among these combinations of the functional groups, the combination of hydroxy group and isocyanate group is preferable in terms of easiness of reaction control. Among these, combination of the (meth)acrylic copolymer (A) having a hydroxy group and the compound having an isocyanate group is preferable.

Examples of the isocyanate group having the polymerizable carbon double bond group include the aforementioned 2-(meth)acryloyloxyethyl isocyanate and alkylene oxide adduct thereof.

A content of the compound having the functional group that can reac with these functional groups and the polymerizable carbon double bond group is preferably not greater than parts by mass, more preferably not greater than 8 parts by mass, further preferably not greater than 5 parts by mass, and particularly preferably not greater than 3 parts by mass relative to 100 parts by mass of the (meth)acrylic copolymer (A) from the viewpoint of improvement of adhesiveness and stress relaxation. In terms of reaction efficiency, the content is preferably not less than 1 part by mass.

A weight-average molecular weight (Mw) of the (meth)acrylic copolymer (A) is preferably 600,000 to 1,500,000, more preferably 700,000 to 1,200,000, and further preferably 800,000 to 1,100,000, from the viewpoint of obtaining the adhesive composition having high aggregation force.

The weight-average molecular weight of the (meth)acrylic copolymer (A) within the above range tends to yield the adhesive composition having high aggregation force, and tends to yield excellent operability and uniformly starring ability.

In the present adhesive sheet, the weight-average molecular weight (Mw) can be determined as follows, for example.

### (Method for Measuring Weight-Average Molecular Weight)

A measurement sample is prepared by dissolving 4 mg of the (meth)acrylic copolymer (A) in 12 mL of tetrahydrofuran (THF), and a molecular-weight distribution curve is measured under the following conditions by using a gel permeation chromatography (GPC) analyzer (HLC-8320 GPC available from Tosoh Co. Ltd.) to determine the weight-average molecular weight (Mw).
Guard column: TSK guard column HXL
Separation column: TSK gel GMHXL (four columns)
Temperature: 40° C.
Injection amount: 100 μL
In terms of polystyrene
Solvent: THF
Flow rate: 1.0 mL/min.

A glass transition temperature (Tg) of the (meth)acrylic copolymer (A) is preferably not greater than −20° C., more preferably not greater than −23° C., further preferably not greater than 25° C., and particularly preferably not greater than −30° C., in terms of inhibition of increase in a storage shearing elastic modulus (G′) at low temperature. The lower limit of the glass transition temperature (Tg) is typically −50° C.

In the present adhesive sheet, the glass transition temperature (Tg) of the (meth)acrylic copolymer (A) can be determined by using a dynamic viscoelasticity measurement apparatus and reading a temperature at which a loss tangent (loss elastic modulus G″/storage shearing elastic modulus G′=tanδ) in measuring the dynamic viscoelasticity with a shearing mode at a frequency of 1 Hz becomes maximum.

For example, the (meth)acrylic copolymer (A) is molded into a cylinder with 8 mm in diameter (height: 1.0 mm), and a loss tangent (tan δ) of this cylinder can be measured by using a viscoelasticity measuring apparatus (DHR 2, available from TA. Instruments) under the following measurement conditions.

### (Measurement Conditions)

Measurement tool: D 8 mm parallel plate
Strain: 0.1%
Frequency: 1 Hz
Measurement temperature: −60 to 100° C.
Temperature raising rate: 5° C./min.

### Photocurable Compound (B)

The photocurable compound (B) is a compound having curability by light irradiation.

Containing the photocurable compound (B) in the adhesive composition can regulate rheologic properties and adhesiveness to an adherent of the adhesive composition.

Examples of the photocurable compound (B) include (meth)acrylic monomers and (meth)acrylic oligomers, and use of these compounds is preferable because the storage shearing elastic modulus (G′) and the glass transition temperature (Tg) of the adhesive composition are easily regulated.

For example, blending a monofunctional (meth)acrylic monomer or monofunctional (meth)acrylic oligomer in which a homopolymer thereof has a glass transition temperature (Tg) lower than the glass transition temperature (Tg) of the (meth)acrylic copolymer (A) can lower the glass transition temperature (Tg) of the adhesive composition, and tends to improve softness at a low temperature (for example, −20° C.) and to yield excellent bending resistance at this temperature.

Use of a polyfunctional (meth)acrylic monomer or polyfunctional (meth)acrylic oligomer having two or more functional groups forms a crosslinking structure, and tends to impart aggregation force and appropriate toughness to the adhesive layer (adhesive sheet). Further, the adhesive layer having appropriate toughness can prevent deformation and collapse of the adhesive layer in cutting. Moreover, even if stress is applied after the constituent members of the image display device are bonded, the surface of the constituent members does not undulate, and tends to yield excellent recovering ability.

The photocurable compound (B) may be used singly or in combination. Among these, the (meth)acrylic oligomer is preferable, and the monofunctional (meth)acrylic oligomer is preferably contained as a main component.

As the monofunctional (meth)acrylicmonomer, the compounds exemplified as the (meth)acrylate monomer used as the structural unit of the (meth)acrylic copolymer (A) may be appropriately used.

Among these, a (meth)acrylate monomer in which a homopolymer thereof has a glass transition temperature (Tg) of not greater than −20° C., preferably not greater than −30° C., and more preferably not greater than 40° C. is preferable from the viewpoint of imparting softness to the adhesive sheet. The lower limit of the glass transition temperature (Tg) is not particularly limited, and −100° C., for example.

From the viewpoint of imparting adhesiveness to the adherend, a (meth)acrylic monomer having a polar group and/or an alkylene oxide skeleton is preferable.

Examples of the monofunctional (meth)acrylic oligomer include monofunctional polyester (meth)acrylate oligomer, monofunctional epoxy (meth)acrylate oligomer, monofunctional urethane (meth)acrylate oligomer, and monofunctional polyether (meth)acrylate oligomer.

Among these, the monofunctional urethane (meth)acrylate oligomer is preferable from the viewpoint of obtaining a cured product having appropriate toughness and softness and excellent adhesiveness to the adherend.

The monofunctional urethane (meth)acrylate oligomer is obtained by reacting polyol, polyisocyanate, and hydroxy-group-containing mono(meth)acrylate or isocyanate-group-containing mono(meth)acrylate, for example.

As the polyol, polyols commonly used for urethane (meth)acrylate oligomers can be used, and examples thereof include: polyether polyols such as polyethylene glycol, polypropylene glycol, and polytetramethylene glycol; condensed polymers between polyvalent carboxylic acid, such as phthalic acid, adipic acid, and maleic acid, and polyhydric alcohol, such as ethylene glycol, propylene glycol, butylene glycol, diethylene glycol, trimethylolpropane, and pentaerythritol; polyester polyols such as ring-opening polymer of cyclic ester (lactone); and polycarbonate polyols such as 1,6-hexanediol carbonate polyol. These may be used singly or in combination. Among these, polyether polyol is preferable, and polypropylene glycol is particularly preferable.

Examples of the polyisocyanate include: polyvalent isocyanates such as aliphatic polyvalent isocyanates such as hexamethylene diisocyanate, trimethylhexamethylene diisocyanate, lysine diisocyanate, and lysine triisocyanate, alicyclic polyvalent isocyanates such as hydrogenated xylene diisocyanate, hydrogenated diphenylmethane diisocyanate, isophorone diisocyanate, and norbornene diisocyanate, and aromatic polyvalent isocyanates such as tolylene diisocyanate, diphenylmethane diisocyanate, polyphenylmethane polyisocyanate, modified diphenylmethane diisocyanate, xylylene diisocyanate, tetramethylxylylene diisocyanate, phenylene diisocyanate, and naphthalene diisocyanate; trimer compounds of the above polyvalent isocyanate; and multimer compounds of the above polyvalent isocyanate. Examples of the polyisocyanate also include allophanate-type polyisocyanate and biuret-type polyisocyanate. These may be used singly or in combination.

Examples of the hydroxy-group-containing mono(meth)acrylate include: hydroxy (meth)acrylates such as 2-hydroxyethyl (meth)acrylate, 4-hydroxybutyl (meth)acrylate, 5-hydroxypentyl (meth)acrylate, 6-hydroxyhexyl (meth)acrylate, and 8-hydroxyoctyl (meth)acrylate; caprolactone-modified hydroxy (meth)acrylates such as caprolactone-modified 2-hydroxyethyl (meth)acrylate; oxyalkylene-modified (meth)acrylates such as diethylene glycol (meth)acrylate and polyethylene glycol (meth)acrylate; primary-hydroxy-group-containing (meth)acrylates such as 2-acryloyloxyethyl-2-hydroxyethylphthalic acid; secondary-hydroxy-group-containing (meth)acrylates such as 2-hydroxypropyl (meth)acrylate, 2-hydroxybutyl (meth)acrylate, and 3-chloro-2-hydroxypropyl (meth)acrylate; and tertiary-hydroxy-group-containing (meth)acrylates such as 2,2-dimethyl-2-hydroxyethyl (meth)acrylate. These may be used singly or in combination.

Among these, the primary-hydroxy-group-containing (meth)acrylate is preferable in terms of reactivity, and 2-hydroxyethyl (meth)acrylate and 4-hydroxybutyl (meth)acrylate are particularly preferable in terms of durability and low-temperature softness.

Examples of the isocyanate-group-containing mono(meth)acrylate include 2-isocyanatoethyl (meth)acrylate, 1,1-bis(acryloyloxymethyl)ethyl isocyanate, and 2-(0-[1′-methylpropylideneamino]carboxyamino)ethyl methacrylate. Among these, 2-isocyanatoethyl (meth)acrylate is preferable.

The monofunctional (meth)acrylic oligomer has a weight-average molecular weight (Mw) of typically not less than 5,000, more preferably not less than 7,000, and further preferably not less than 9,000. The upper limit is not particularly limited, but for example 100,000.

The monofunctional (meth)acrylic oligomer being a compound having such a weight-average molecular weight tends to be able to inhibit change in time of bleeding out while keeping compatibility with the (meth)acrylic copolymer (A).

For the measurement of the weight-average molecular weight of the photocurable compound (B), the method for measuring the weight-average molecular weight of the (meth)acrylic copolymer (A) applies mutatis mutandis, as necessary.

The monofunctional (meth)acrylic oligomer may be used in combination with polyfunctional (meth)acrylic oligomer described later. In this case, an average number of (meth)acryloyl groups in the (meth)acrylic oligomer components is not particularly limited, but typically approximately 1.1 to 4, and preferably approximately 1.2 to 3. The average number of the (meth)acryloyl groups within such a range tends to form an appropriate crosslinking structure in the adhesive while keeping softness and adhesiveness to the adherent.

Note that the average number of the (meth)acryloyl groups means an average number of (meth)acryloyl groups present in one molecule of the (meth)acrylic oligomer.

The monofunctional (meth)acrylicoligomer has a glass transition temperature (Tg) after light-curing of typically not greater than −20° C., preferably not greater than −30° C., and more preferably not greater than 40° C. The lower limit of the glass transition temperature (Tg) is not particularly limited, and for example, −100° C.

The monofunctional (meth)acrylic oligomer having the glass transition temperature (Tg) within such a range imparts softness to resist buckling in bending deformation, and yields the adhesive sheet also having recovering ability.

The glass transition temperature (Tg) of the monofunctional (meth)acrylic oligomer after light-curing refers to a glass transition temperature (Tg) measured by adding 3 parts by mass of the photopolymerization initiator into 100 parts by mass of the monofunctional (meth)acrylic oligomer to form a resin composition, and curing the resin composition by irradiation with UV so that an integrated light quantity at a wavelength of 365 nm is 1000 mJ/cm².

In the present disclosure, “photo-curability” means reactivity (curability) to general radiation. Specifically, the photo-curability means curability by light within a wavelength region of 200 nm to 780 nm, and is particularly preferably used to mean reactivity (curability) to UV.

Examples of the polyfunctional (meth)acrylic monomer include 1,4-butanediol di(meth)acrylate, glycerol di(meth)acrylate, neopentyl glycol di(meth)acrylate, glycerol glycidyl ether di(meth)acrylate, 1,6-hexanediol di(meth)acrylate, 1,9-nonanediol di(meth)acrylate, tricyclodecanedimethanol dimethacrylate, tricyclodecanedimethanol di(meth)acrylate, bisphenol A polyethoxy di(meth)acrylate, bisphenol A polypropoxy di(meth)acrylate, bisphenol F polyethoxy di(meth)acrylate, ethylene glycol di(meth)acrylate, neopentyl glycol di(meth)acrylate, trimethylolpropanetrioxyethyl (meth)acrylate, s-caprolactone-modified tris(2-hydroxyethyl) isocyanurate tri(meth)acrylate, pentaerythritol tri(meth)acrylate, propoxylated pentaerythritol tri(meth)acrylate, ethoxylated pentaerythritol tri(meth)acrylate, pentaerythritol tetra(meth)acrylate, propoxylated pentaerythritol tetra(meth)acrylate, ethoxylated pentaerythritol tetra(meth)acrylate, dipentaerythritol hexa(meth)acrylate, polyethylene glycol di(meth)acrylate, polypropylene glycol di(meth)acrylate, polytetramethylene glycol di(meth)acrylate, tris(acryloxyethyl) isocyanurate, dipentaerythritol penta(meth)acrylate, tripentaerythritol hexa(meth)acrylate, tripentaerythritol penta(meth)acrylate, neopentyl glycol hydroxypivalate di(meth)acrylate, di(meth)acrylate of ε-caprolactone adduct of neopentyl glycol hydroxypivalate, trimethylolpropane tri(meth)acrylate, trimethylolpropane polyethoxy tri(meth)acrylate, and ditrimethylolpropane tetra(meth)acrylate.

Among these, the polyfunctional (meth)acrylic monomers having a polyalkylene oxide skeleton, such as polyethylene glycol di(meth)acrylate, polypropylene glycol di(meth)acrylate, and polytetramethylene glycol di(meth)acrylate are preferable from the viewpoint of imparting appropriate toughness to the cured product.

The weight-average molecular weight of the polyfunctional (meth)acrylic monomer is typically not less than 100, preferably not less than 200, and further preferably not less than 250 from the viewpoint of imparting appropriate softness to the cured product. The upper limit is typically 1000.

For curing the adhesive composition with visible light, the photocurable compound (B) is preferably the polyfunctional (meth)acrylic oligomer in terms of obtaining the cured product having high toughness, in other words, obtaining the cured product having appropriate softness.

Examples of the polyfunctional (meth)acrylic oligomer include polyfunctional (meth)acrylic oligomers such as polyfunctional polyester (meth)acrylic oligomer, polyfunctional epoxy (meth)acrylic oligomer, polyfunctional urethane (meth)acrylic oligomer, and polyfunctional polyether (meth)acrylic oligomer.

Among these, the polyfunctional urethane (meth)acrylic oligomer is preferable from the viewpoint of imparting appropriate toughness to the cured product.

The polyfunctional urethane (meth)acrylate oligomer can be obtained by, for example, reacting a hydroxy-group-containing (meth)acrylate with a compound having isocyanate groups at both ends obtained by reacting a polyol and a polyisocyanate.

Examples of the polyol include the aforementioned polyols. These may be used singly or in combination. Among these, polyether polyol is preferable, and polypropylene glycol is particularly preferable.

Examples of the polyisocyanate include the aforementioned polyisocyanates. These may be used singly or in combination.

Examples of the hydroxy-group-containing (meth)acrylate include the hydroxy-group-containing (meth)acrylates described in the (meth)acrylic copolymer (A). These may be used singly or in combination. Among these, the primary-hydroxy-group-containing (meth)acrylate is preferable, and 2-hydroxyethyl (meth)acrylate is more preferable.

The polyfunctional urethane (meth)acrylic oligomer is preferably polyfunctional urethane (meth)acrylic oligomer having a polyalkylene oxide skeleton, and particularly preferably polyfunctional urethane (meth)acrylic oligomer having a propylene glycol skeleton.

A weight-average molecular weight of the polyfunctional urethane (meth)acrylic oligomer is typically not less than 3,000, preferably not less than 5,000, further preferably not less than 8,000, and particularly preferably not less than 10,000. The upper limit of the weight-average molecular weight is typically 100,000.

A content of the photocurable compound (B) is preferably not less than 1 part by mass, more preferably not less than 2 parts by mass, further preferably not less than 4 parts by mass, and particularly preferably not less than 10 parts by mass relative to 100 parts by mass of the (meth)acrylic copolymer (A) from the viewpoint of imparting shape stability of the adhesive sheet and durability when forming a laminate.

The upper limit of the content of the photocurable compound (B) is preferably not greater than 100 parts by mass, more preferably not greater than 60 parts by mass, further preferably not greater than 40 parts by mass, and particularly preferably not greater than 30 parts by mass relative to 100 parts by mass of the (meth)acrylic copolymer (A) from the viewpoint of achievement of adhesiveness.

In addition to the photocurable compound (B), a thermal crosslinker may be used in combination in terms of further increase in the crosslinking density to improve long-term reliability.

Examples of such a thermal crosslinker include isocyanate-based crosslinker, epoxy-based crosslinker, aziridine-based crosslinker, melamine-based crosslinker, aldehyde-based crosslinker, amine-based crosslinker, and metal-chelate-type crosslinker. Among these, the isocyanate-based crosslinker is preferably used in terms of excellent reactivity with the (meth)acrylic copolymer (A).

### Photopolymerization Initiator (C)

The photopolymerization initiator (C) may be any compound that generates radicals with active energy radiation.

The photopolymerization initiator (C) is largely classified into two types with its radical generation mechanism: a cleavage-type photopolymerization initiator in which a single bond in the initiator itself can be cleaved and decomposed to generate radicals; and a hydrogen abstraction-type photopolymerization initiator in which an excited initiator and a hydrogen donner in the system can form an exciplex to transfer hydrogen in the hydrogen donner.

The photopolymerization initiator (C) may be any of the cleavage-type photopolymerization initiator and the hydrogen abstraction-type photopolymerization initiator, each of them may be used singly or may be mixed for use, and one or more of them may be each used in combination.

In the present disclosure, the hydrogen abstraction-type photopolymerization initiator is preferably used in terms of efficient crosslinking without requiring a functional group such as a double bond between carbons in the acrylic polymer (A) itself.

Examples of the cleavage-type photopolymerization initiator include 2,2-dimethoxy-1,2-diphenylethan-1-one, 1-hydroxycyclohexyl phenyl ketone, 2-hydroxy-2-methyl-1-phenylpropan-1-one, 1-(4-(2-hydroxyethoxy)phenyl)-2-hydroxy-2-methyl-1-propan-1-one, 2-hydroxy-1-[4-{4-(2-hydroxy-2-methyl-propionyl)benzyl}phenyl]-2-methylpropan-1-one, oligo(2-hydroxy-2-methyl-1-(4-(methylvinyl)phenyl)propanone), methyl phenylglyoxylate, 2-benzyl-2-dimethylamino-1-(4-morpholinophenyl)butan-1-one, 2-methyl-1-[4-(methylthio)phenyl]-2-morpholinopropan-1-one, 2-(dimethylamino)-2-[(4-methylphenyl)methyl]-1-[4-(4-morpholinyl)phenyl]-1-butanone, bis(2,4,6-trimethylbenzoyl)-phenylphosphine oxide, 2,4,6-trimethylbenzoyldiphenylphosphine oxide, (2,4,6-trimethylbenzoyl)ethoxyphenylphosphine oxide, bis(2,6-dimethoxybenzoyl)-2,4,4-trimethylpentylphosphine oxide, and derivatives thereof.

Examples of the hydrogen abstraction-type photopolymerization initiator include benzophenone, 4-methylbenzophenone, 2,4,6-trimethylbenzophenone, 4-phenylbenzophenone, 3,3′-dimethyl-4-methoxybenzophenone, 4-(meth)acryloyloxybenzophenone, methyl 2-benzoylbenzoate, methyl benzoylformate, bis(2-phenyl-2-oxoacetate)oxybisethylene, 4-(1,3-acryloyl-1,4,7,10,13-pentaoxotridecyl)benzophenone, thioxanthone, 2-chlorothioxanthone, 3-methylthioxanthone, 2,4-dimethylthioxanthone, 2-methylanthraquinone, 2-ethylanthraquinone, 2-t-butylanthraquinone, 2-aminoanthraquinone, and derivatives thereof. Among these, 4-methylbenzophenone and 2,4,6-trimethylbenzophenone are preferable.

A content of the photopolymerization initiator (C) is preferably typically 0.1 to 10 parts by mass, preferably 0.5 to 5 parts by mass, and more preferably 1 to 3 parts by mass relative to 100 parts by mass of the (meth)acrylic copolymer (A). The content of not less than the above lower limit tends to prevent curing failure, and the content of not greater than the above upper limit tends to easily inhibit decrease in solution stability, such as precipitation from the adhesive composition, to inhibit problems of embrittlement and coloring.

The adhesive composition contains the (meth)acrylic copolymer (A), the photocurable compound (B), and the photopolymerization initiator (C), and preferably further contains a silane coupling agent (D). The adhesive composition may contain other components described later.

### Silane Coupling Agent (D)

The silane coupling agent is an organic silicon compound having one or more reactive functional groups and one or more alkoxy groups bonded to a silicon atom in the structure. Examples of the reactive functional groups include epoxy group, (meth)acryloyl group, mercapto group, hydroxy group, carboxy group, amino group, amide group, and isocyanate group. Among these, epoxy group and mercapto group are preferable in terms of balance of durability.

As the alkoxy group bonded to a silicon atom, an alkoxy group having 1 to 8 carbon atoms is preferably contained in terms of durability and storage stability, and methoxy group and ethoxy group are particularly preferable.

The silane coupling agent (D) may have an organic substituent other than the reactive functional group and the alkoxy group bonded to a silicon atom, such as, for example, alkyl group and phenyl group.

Examples of the silane coupling agent (D) include: monomer-type epoxy group-containing silane coupling agents being silane compounds such as 3-glycidoxypropyltrimethoxysilane, 3-glycidoxypropyltriethoxysilane, 3-glycidoxypropylmethyldiethoxysilane, 3-glycidoxypropylmethyldimethoxysilane, and 2-(3,4-epoxycyclohexyl)ethyltrimethoxysilane; oligomer-type epoxy-group-containing silane coupling agents being silane compounds in which a part of the above silane compound is hydrolytically condensing-polymerized or in which the above silane compound and an alkyl-group-containing silane compound, such as methyltriethoxysilane, ethyltriethoxysilane, methyltrimethoxysilane, and ethyltrimethoxysilane, are co-condensed;
monomer-type mercapto-group-containing silane coupling agents being silane compounds such as 3-mercaptopropyltrimethoxysilane, 3-mercaptopropyltriethoxysilane, γ-mercaptopropyldimethoxymethylsilane, and 3-mercaptopropylmethyldimethoxysilane; oligomer-type mercapto-group-containing silane coupling agents being silane compounds in which a part of the above silane compound is hydrolytically condensing-polymerized or in which the above silane compound and an alkyl group-containing silane compound, such as methyltriethoxysilane, ethyltriethoxysilane, methyltrimethoxysilane, and ethyltrimethoxysilane, are co-condensed;
(meth)acryloyl-group-containing silane coupling agents, such as 3-acryloxypropyltrimethoxysilane, 3-methacryloxypropyltrimethoxysilane, 3-methacryloxypropylmethyldiethoxysilane, 3-methacryloxypropyltriethoxysilane, and 3-acryloxypropyltrimethoxysilane;
amino-group-containing silane coupling agents, such as N-2-(aminoethyl)-3-aminopropylmethyldimethoxysilane, N-2-(aminoethyl)-3-aminopropyltrimethoxysilane, 3-aminopropyltrimethoxysilane, 3-aminopropyltriethoxysilane, 3-triethoxysilyl-N-(1,3-dimethyl-butylidene)propylamine, and N-phenyl-3-aminopropyltrimethoxysilane;
isocyanate-group-containing silane coupling agents, such as 3-isocyanatepropyltriethoxysilane; and
vinyl-group-containing silane coupling agents, such as vinyltrimethoxysilane and vinyltriethoxysilane.

These may be used singly, or two or more of these may be used in combination.

Among these, the epoxy-group-containing silane coupling agent and the mercapto-group-containing silane coupling agent are preferably used, and specifically, the epoxy-group-containing silane coupling agent is preferable, and 3-glycidoxypropyltrimethoxysilane is particularly preferable in terms of excellent durability.

A content of the silane coupling agent (D) is preferably 0.005 to 10 parts by mass, particularly preferably 0.01 to 5 parts by mass, and further preferably 0.05 to 1 part by mass relative to 100 parts by mass of the (meth)acrylic copolymer (A). The content of not less than the above lower limit tends to improve durability, and the content of not greater than the above upper limit tends to improve durability.

### Other Components

The adhesive component can appropriately contain various additives as “other components” as necessary at an extent not impairing the effect of the present disclosure. Examples of the other components include plasticizer, UV absorber, antirust agent, tackifier resin, antioxidant, light stabilizer, metal deactivator, antiaging agent, moisture absorber, and inorganic particles.

As necessary, reaction catalysts such as tertiary amine compound, quaternary ammonium compound, and tin laurate compound may be appropriately contained.

These may be used singly, or two or more of these may be used in combination.

### (Plasticizer)

The plasticizer is a material for softening a resin with a high elastic modulus to improve processability and flexibleness. Examples of the plasticizer include monofunctional (meth)acrylic oligomers such as polyester (meth)acrylate, urethane (meth)acrylate, and polyether (meth)acrylate. Among these, the urethane (meth)acrylate oligomer is preferable from the viewpoint of imparting appropriate toughness to the cured product.

### (UV Absorber)

Examples of the UV absorber include benzophenone-based UV absorbers, benzotriazole-based UV absorbers, triazine-based UV absorbers, salicylic acid-based UV absorbers, cyanoacrylate-based UV absorbers, and benzoxazine-based UV absorbers. These UV absorbers may be used singly or in combination.

A content of the UV absorber is preferably 0.01 to 20 parts by mass, particularly preferably 0.1 to 15 parts by mass, and further preferably 0.5 to 10 parts by mass relative to 100 parts by mass of the (meth)acrylic copolymer (A). The content of not less than the above lower limit tends to improve light-resistant reliability, and the content of not greater than the above upper limit tends to improve yellowing resistance.

(Antirust Agent) The antirust agent is preferably triazoles and benzotriazoles, for example. The antirust agent can prevent corrosion of the optical member.

A content of the antirust agent is preferably 0.01 to5 parts by mass, and specifically preferably 0.1 to 3 parts by mass relative to 100 parts by mass of the (meth)acrylic copolymer (A).

A content of the other components is preferably not greater than 5 parts by mass, particularly preferably not greater than 1 part by mass, and further preferably not greater than 0.5 parts by mass relative to 100 parts by mass of the (meth)acrylic copolymer (A), and the lower limit is typically 0 parts by mass. An excessively large content thereof tends to decrease compatibility with the (meth)acrylic copolymer (A) to deteriorate transparency and durability.

The adhesive composition is prepared by mixing predetermined amounts of the (meth)acrylic copolymer (A), the photocurable compound (B), the photopolymerization initiator (C), preferably the silane coupling agent (D), and as necessary the other components.

The adhesive composition obtained as above can be subjected to the adhesive sheet, specifically the adhesive sheet for a constituent member of a flexible image display device.

### <Adhesive Sheet>

The adhesive sheet and the adhesive sheet for a constituent member of a flexible image display device according to an embodiment of the present disclosure (hereinafter, which may be generally abbreviated as “the present adhesive sheet”) can be manufactured as follows, for example. The manufacturing method is not limited to this method.

For manufacturing the present adhesive sheet, the adhesive composition containing the (meth)acrylic copolymer (A), the photocurable compound (B), the photopolymerization initiator (C), preferably the silane coupling agent (D), the other components as necessary, etc., is prepared. This adhesive composition is formed into a sheet, and the sheet is subjected to crosslinking, namely a polymerization reaction to be cured and appropriately processed as necessary to manufacture the present adhesive sheet.

When the adhesive composition for forming the present adhesive sheet is prepared, the raw materials are kneaded by using a temperature-controllable kneader (for example, a uniaxial extruder, a biaxial extruder, a planetary mixer, a biaxial mixer, and a pressurizing kneader).

When the raw materials are mixed, the additives such as the silane coupling agent (D) and the antioxidant may be blended with the resin in advance and then supplied into the kneader, all the materials may be melt-nixed in advance and then supplied, or only the additives may be condensed into the resin in advance to produce a master batch and then supplied.

Then, the obtained adhesive composition is dissolved in an appropriate solvent, and the adhesive composition is formed into a sheet by using coating methods.

Such a solvent is not particularly limited as long as the solvent dissolves the adhesive composition. Examples of the solvent include: ester solvents, such as methyl acetate, ethyl acetate, methyl acetoacetate, and ethyl acetoacetate; ketone solvents, such as acetone, methyl ethyl ketone, and methyl isobutyl ketone; aromatic solvents, such as toluene and xylene; and alcohol solvents, such as methanol, ethanol, and propyl alcohol. These may be used singly, or two or more of these may be used in combination. Among these, ethyl acetate, acetone, methyl ethyl ketone, and toluene are preferable in terms of solubility, a drying property, price, etc., and ethyl acetate is particularly preferably used.

A content of the solvent is preferably not greater than 600 parts by mass, more preferably not greater than 500 parts by mass, further preferably not greater than 400 parts by mass, and particularly preferably not greater than 350 parts by mass relative to 100 parts by mass of the (meth)acrylic copolymer (A) in terms of a drying property. Meanwhile, the content is preferably not less than 1 part by mass, more preferably not less than 50 parts by mass, further preferably not less than 100 parts by mass, and particularly preferably not less than 150 parts by mass.

The adhesive composition is dissolved in the solvent, then the solution is applied on a release film, dried, and cured by irradiation with active energy radiation to form the present adhesive sheet. That is, the present adhesive sheet is preferably an adhesive sheet with a release film having a configuration in which the present adhesive sheet and a release film are laminated.

As such a release film, known release films can be appropriately used. As a material of the release film, a film, such as a polyester film, a polyolefin film, a polycarbonate film, a polystyrene film, an acryl film, a triacetylcellulose film, and a fluororesin film, subjected to a releasing treatment by applying a silicone resin; and release paper can be appropriately selected for use, for example.

A thickness of the release film is not particularly limited. Specifically, the thickness is preferably 10 to 250 μm, more preferably 25 to 200 μm, and further preferably 35 to 190 μm from the viewpoints of, for example, processability and handleability.

As necessary, the release film may be subjected to an emboss process or various texturing processes (such as a corn shape, pyramid shape, or a hemispherical shape).

For a purpose of improving adhesiveness to each member sheet, the surface of the release film may be subjected to surface treatments such as a corona treatment, a plasma treatment, and a primer treatment.

The coating can be performed by a commonly used method such as roll coating, die coating, gravure coating, comma coating, screen printing, and bar coating, for example.

The coating is preferably performed so that a thickness of the adhesive composition after drying is 1 to 200 μm in terms of effectively exhibiting the effect of the present disclosure. The coating is performed so that the thickness is more preferably 5 to 100 μm, and further preferably 10 to 50 μm.

Examples of the drying method include drying with a drying apparatus or a heat roller, and drying by blowing hot air to the film. Among these, a drying apparatus is preferably used in terms of uniform and easy drying. These may be used singly, or two or more of these may be used in combination.

The drying temperature is typically 40 to 150° C., more preferably 45 to 140° C., further preferably 50 to 130° C., and particularly preferably 55 to 120° C. The above temperature range can efficiently and relatively safely remove the solvent while inhibiting thermal deformation of the release film.

The drying time is typically 1 to 30 minutes, more preferably 3 to 25 minutes, and further preferably 5 to 20 minutes. The above time range can efficiently and sufficiently remove the solvent.

In the drying, the solvent content after the drying is preferably not greater than 1 mass %, more preferably not greater than 0.5 mass %, particularly preferably not greater than 0.1 mass %, and most preferably 0 mass %.

Irradiation energy, an irradiation time, an irradiation method, etc., of the active energy radiation are not particularly limited as long as the photopolymerization initiator (C) is activated to polymerize the monomer components.

When the hydrogen abstraction-type photopolymerization initiator is used as the photopolymerization initiator (C), the (meth)acrylic copolymer (A) is also subjected to the hydrogen abstraction reaction and the (meth)acrylic copolymer (A) is incorporated into the crosslinked structure, which can form a crosslinked structure with many crosslinking points.

Therefore, the present adhesive sheet is preferably a cured product produced by using the hydrogen abstraction-type photopolymerization initiator.

Examples of the active energy radiation in the irradiation with active energy radiation include: rays, such as far UV, UV near UV, infrared ray, and visible ray; and ionizing radiations, such as X-ray, α-ray, β-ray, γ-ray, electron beam, proton beam, and neutron beam. Among these, UV is preferable from the viewpoints of reduction in damage of constituent members of an optical apparatus and reaction control.

In addition, curing with UV irradiation is advantageous in terms of a curing rate, easy availability of the irradiation apparatus, price, etc.

Examples of a light source of the UV irradiation include use of a high-pressure mercury lamp, an ultrahigh-pressure mercury lamp, a carbon arc lamp, a metal halide lamp, a xenon lamp, a chemical lamp, an electrodeless discharge lamp, or an LED, which emit light with a wavelength region of 150 to 450 nm. Among these, a high-pressure mercury lamp is preferably used.

The irradiation is performed under a condition of an irradiation dose (integrated light quantity) of the active energy radiation of preferably 30 to 3,000 mJ/cm², more preferably 100 to 2,000 mJ/cm², and further preferably 300 to 1,500 mJ/cm² in terms of curing. After the active energy radiation, heating may be performed as necessary to increase a curing degree.

The adhesive composition is cured by irradiation with the active energy radiation to form the present adhesive sheet. A thickness of the formed present adhesive sheet is preferably 1 to 200 μm, particularly preferably 5 to 100 μm, and further preferably 10 to 50 μm. The thickness of not less than the lower limit tends to stabilize the adhesion property. The thickness of not greater than the upper limit tends to be efficiently dried, and can reduce a risk of glue ooze, etc., when formed into a roll. The thickness of the present adhesive sheet can be regulated by a coating thickness and a solid content concentration of a coating liquid.

The obtained present adhesive sheet may be crosslinked by irradiation with active energy radiation for preliminary curing so as to have latent reactivity with active energy radiation, in other words, so as to remain reactivity with active energy radiation. When the preliminary curing is performed, each of the layers is crosslinked by irradiation with the active energy radiation via the release film. In this case, a degree of the crosslinking with the active energy radiation (gel fraction) can be regulated by controlling an irradiation dose of the active energy radiation, but as noted above, the degree of the crosslinking with the active energy radiation (gel fraction) can also be regulated by irradiation with UV via the release film to partially shielding the active energy radiation.

On the present adhesive sheet, a release film may be further laminated as necessary. In this case, it is acceptable that the adhesive composition is applied on the release film, dried, and then cured by irradiation with active energy radiation, and the release film is laminated thereon. Alternatively, it is also acceptable that the adhesive composition is applied on the release film and dried, the release film is laminated, and then the laminate is cured by irradiation with active energy radiation to form the present adhesive sheet.

When the present adhesive sheet is manufactured by using the above coating method, the present adhesive sheet may also be obtained by thermal curing, other than the curing by irradiation with active energy radiation.

As another embodiment for forming the adhesive composition into a sheet to manufacture the present adhesive sheet, usable is a known method such as, for example, a wet-laminating method, a dry-laminating method, an extrusion casting method using a T-die, an extrusion laminating method, a calendar method, an inflation method, an injection molding method, and a liquid-injecting curing method. Among these, a wet-laminating method, an extrusion casting method, and an extrusion laminating method are preferable for manufacturing the sheet.

Further, the present adhesive sheet may also be formed by preparing the adhesive composition, applying this composition on a surface-protective film or an image display device constituent member, described later, and curing the adhesive composition.

A gel fraction of the present adhesive sheet is preferably 30 to 95 mass %, more preferably 35 to 90 mass %, and further preferably 40 to 85 mass %. The gel fraction of not less than the above lower limit is preferable because a risk of glue ooze in time tends to be reduced. The gel fraction is an indicator of a crosslinking degree (degree of curing), and can be measured under measurement conditions in the Example, as described later.

An adhesive force (A) [23° C., 50% RH, peeling angle: 180°, peeling speed: 300 mm/min.] of the present adhesive sheet relative to a polyimide film surface is preferably 4 to 30 N/cm, more preferably 4.5 to 20 N/cm, and further preferably 5 to 15 N/cm. The adhesive force within such a range indicates sufficient adhesiveness, and tends to be suitably used as the adhesive sheet for a surface-protective film for a flexible image display device.

The adhesive force (A) can be measured under measurement conditions in the Example, as described later.

An adhesive force (B) [23° C., 50% RH, peeling angle: 180°, peeling speed: 300 mm/min.] relative to a polyimide film where a mixed liquid of Oleic acid:Squalene=1:1 (an artificial sebum liquid) is dropped onto the present adhesive sheet and the adhesive sheet is stored at 23° C. and 50% RH for five days is preferably 3 to 20 N/cm, more preferably 4 to 15 N/cm, and further preferably 4.5 to 10 N/cm. The adhesive force within such a range indicates sufficient resistance against oil, and tends to be suitably used as the adhesive sheet for a constituent member of a flexible image display device.

The adhesive force (B) can be measured under measurement conditions in the Example, as described later.

An oil-resistant adhesion rate (X) of the present adhesive sheet is preferably not less than 84%, and more preferably not less than 85%. The oil-resistant adhesion rate (X) is determined by the following formula.

Oil-resistant adhesion rate(X)=[Adhesive force(B)/Adhesive force(A)]×100

A glass transition temperature (Tg) of the present adhesive sheet is preferably not greater than −20° C., more preferably not greater than −23° C., further preferably not greater than −25° C., and particularly preferably not greater than −30° C. in terms of inhibition of increase in the storage shearing elastic modulus (G′) at low temperature. The lower limit of the glass transition temperature (Tg) is typically −50° C.

Containing the (meth)acrylic copolymer (A) having the predetermined amount of the structural unit derived from the alkyl (meth)acrylate (a1) tends to allow the adhesive sheet to have excellent oil resistance but insufficient flexibleness. In the present disclosure, however, setting the glass transition temperature of the adhesive sheet within the above range enables to impart the oil resistance and yield excellent flexibleness.

The glass transition temperature (Tg) can be measured under measurement conditions in the Example, as described later.

The present adhesive sheet has a storage shearing elastic modulus (G′) at 20° C. of not greater than 800 kPa. The storage shearing elastic modulus (G′) at 20° C. of not greater than 800 kPa can yield bending resistance at a low temperature (for example, −20° C.). From such a viewpoint, the storage shearing elastic modulus is preferably not greater than 700 kPa, and more preferably not greater than 600 kPa.

The storage shearing elastic modulus (G′) at 20° C. of the present adhesive sheet is preferably not greater than 500 kPa, and more preferably not greater than 400 kPa in terms of prevention of delamination in folding specifically at a high speed or at low temperature. The lower limit is preferably not less than 50 kPa from the viewpoints of prevention of glue ooze and shape retention of the adhesive sheet.

The storage shearing elastic modulus (G′) at −20° C. can be measured under measurement conditions in the Example, as described later.

Containing the (meth)acrylic copolymer (A) having the predetermined amount of the structural unit derived from the alkyl (meth)acrylate (a1) tends to allow the adhesive sheet to have excellent oil resistance but insufficient flexibleness. In the present disclosure, however, setting the storage shearing elastic modulus (G′) at 20° C. of the adhesive sheet within the above range enables to impart the oil resistance and yield excellent flexibleness.

A storage shearing elastic modulus (G′) at 25° C. of the present adhesive sheet is preferably not greater than 200 kPa, more preferably not greater than 100 kPa, and further preferably not greater than 50 kPa in terms of retaining the high adhesiveness. The lower limit is preferably not less than 1 kPa from the viewpoints of prevention of glue ooze and shape retention of the adhesive sheet.

The storage shearing elastic modulus (G′) at 25° C. can be measured under measurement conditions in the Example, as described later.

Recovering ability of the present adhesive sheet is preferably not less than 30%, more preferably not less than 35%, and further preferably not less than 40%. Since higher recovering ability is more preferable, the upper limit is 100%.

The recovering ability can be measured under measurement conditions in the Example, as described later.

The present adhesive sheet is preferably transparent. Being transparent can yield excellent appearance without impairing viewability of the image display surface. The present adhesive sheet being transparent means that the present adhesive sheet has a total light transmittance measured in accordance with JIS K7361-1 (ISO-13468-1) of not less than 50% and a haze value measured in accordance with JIS K7136 (ISO-14782) of not greater than 10%.

The total light transmittance of the present adhesive sheet measured in accordance with JIS K7361-1 (ISO-13468-1) is preferably not less than 80%, more preferably not less than 85%, and further preferably not less than 90% in terms of usefulness for use requiring transparency such as the image display device. A higher upper limit is more preferable, and the upper limit is not particularly limited.

The haze value of the present adhesive sheet measured in accordance with JIS K7136 (ISO-14782) is preferably not greater than 5%, more preferably not greater than 3%, further preferably not greater than 2%, and particularly preferably not greater than 1% in terms of usefulness for use requiring transparency such as the image display device. Lowering the lower limit is more preferable, and the lower limit is not particularly limited.

Examples of methods for regulating the total light transmittance and the haze include: regulating the composition of the (meth)acrylic copolymer (A) and the photocurable compound (B); using a photopolymerization initiator (C) without coloring; and not containing a colorant, particles, etc. An antioxidant may be used to inhibit coloring due to heating or deterioration in time. The method is not limited to these methods.

The present adhesive sheet obtained as above can be laminated with an image display device constituent member to constitute a laminate for a flexible image display device (hereinafter, also referred to as “the present laminate”).

In this case, examples of the “image display device constituent member” include a reflection sheet, a light-conductive plate and a light source, a diffusion film, a prism sheet, an liquid crystal panel, a retardation plate, a glass substrate, a polarizing plate, an organic EL panel, an electrode, an anti-reflection film, a color filter, a touch sensor, a cover glass, a cover plastic, or two or more of these members are integrated to form a composite, or a surface-protective film.

In addition to the above members, another layer such as an antistatic layer, a hard coat layer, an anchor layer, a release layer, an easily adhesive layer, a protective layer, a bleeding-inhibition layer, and a planarizing layer may be interposed, as necessary.

The surface-protective film has a surface hardness at a contact depth of 200 to 400 nm measured with a nano-indenter of preferably not less than 400 MPa, more preferably not less than 450 MPa, and particularly preferably not less than 500 MPa. The upper limit is typically 9 GPa. The surface hardness within such a range yields sufficient scratch resistance and impact resistance when the film forms the laminate for a constituent member of a flexible image display device.

The surface-protective film is preferably a member without change in appearance when subjected to a folding test 200,000 times at 20° C. under a condition of a curvature radium (R)=1.5 mm, and this case is preferable because the film hardly causes folding trace and delamination at the bending portion when the film forms the laminate for a constituent member of a flexible image display device.

In the present disclosure, the surface hardness of the surface-protective film is evaluated by nano-indentation.

The nano-indentation method is typically a method in which the indenter is pressed at a constant load to a predetermined depth (contact depth) of a sample (loading), then the indenter is lifted up until the indenter is separated from the sample (unloading), and mechanical properties of the sample surface is analyzed from a relationship between the displacement and the load in this time (load-displacement curve).

The surface hardness in the present disclosure is calculated under the following measurement conditions with the following formula.

$${H}_{IT} = {F}_{MAX} / {A}_{p}$$

(H_{IT}: Surface hardness, F_{MAX}: Maximum test load, Aₚ: Projected contact area)

### (Measurement Conditions)

Measurement apparatus: available from Bruker, T1980
Maximum load: 1000 μN
Indenter material: Diamond
Indenter shape: Berkovich
Applied load: 1 mN
Contact depth: 300 nm

Examples of the surface-protective film include members such as a polyethylene terephthalate film, a polyimide film, an aramid film, and a glass plate. Among these, the polyethylene terephthalate film is preferable in terms of versatility, the polyimide film is preferable in terms of reduction in the folding angle, the glass plate is preferable in terms of obtaining high surface strength, and the polyimide film and the glass plate are particularly effective in terms of the high surface hardness.

The member may be provided with a coating layer on the surface.

The coating layer is not particularly limited, and examples thereof include an easily adhesive coat layer, a release film, a hard coat layer, an antistatic coat layer, and a fingerprint-resistant layer.

Examples of the layer configuration of the laminate of the surface-protective film and the present adhesive sheet include the following configurations. Note that the configuration is not limited thereto.
(Viewing side) Hard coat/Polyimide film/Adhesive sheet (Organic EL side) (surface hardness: 906 MPa)
(Viewing side) Hard coat/PET film/Adhesive sheet (Organic EL side) (surface hardness: 418 MPa)
(Viewing side) Hard coat/PET film/Adhesive sheet/Glass (Organic EL side) (surface hardness: 376 MPa)
(Viewing side) Hard coat/PET film/Adhesive sheet (Organic EL side) (surface hardness: 484 MPa)

As for a durability test of dynamic bending of the laminate for a constituent member of a flexible image display device, a number of bending at which defects of a bending portion (delamination, breakage, buckling, and floating) do not occur is preferably not less than 40,000, and more preferably not less than 100,000. The number of bending is determined with a U-shape bending cycle evaluation with setting of a curvature radius R=1.5 mm, 60 rpm (1 Hz), 20° C.

As for a durability test of dynamic bending of the laminate for a constituent member of a flexible image display device, a number of bending at which defects of a bending portion (delamination, breakage, buckling, and floating) do not occur is preferably not less than 40,000, and more preferably not less than 100,000. The number of bending is determined with a U-shape bending cycle evaluation with setting of a curvature radius R=1.5 mm, 60 rpm (1 Hz), −20° C.

As for a durability test of dynamic bending of the laminate for a constituent member of a flexible image display device, a storage time in which defects of a bending portion (delamination, breakage, buckling, and floating) do not occur is preferably not less than 24 hours, and more preferably not less than 120 hours. The storage time is determined by retaining the bent state with a curvature radius R=1.5 mm, 85° C., and 85% RH.

### <Flexible Image Display Device>

An example of the flexible image display device is: an image display device having a structure in which the present laminate is incorporated in a housing of the flexible image display device; or an image display device having a structure in which the present laminate composed of the laminate configuration of the present adhesive sheet and the surface-protective film is laminated onto the viewing side surface of the image display device.

Examples of such a flexible image display device include a bendable device with the image display surface having a curved shape, a foldable device that can be repeatedly folded, a rollable device that can be wound, and a stretchable device that is stretched. Examples of the image display device include a liquid crystal display, an organic EL display, an inorganic EL display, an electronic paper, a plasma display, and a micro electromechanical system (MEMS) display.

### EXAMPLES

Hereinafter, the present disclosure will be specifically described with Examples. Note that the present disclosure is not limited at all by the following Examples.

### Example 1

Performed was random copolymerization of 40 parts by mass of n-butyl acrylate (homopolymer Tg: −55° C.) as an alkyl (meth)acrylate (a1), 40 parts by mass of 2-ethylhexyl acrylate (homopolymer Tg: −70° C.) as a (meth)acrylate (a2) in which a homopolymer thereof had a glass transition temperature lower than that of the alkyl (meth)acrylate (a1), 17.5 parts by mass of hydroxyethyl acrylate (Tg: −15° C.) as a polar-group-containing monomer (a3), and 2.5 parts by mass of methyl acrylate (Tg: 10° C.) to obtain a (meth)acrylic copolymer (A-1). Into 100 parts by mass of the obtained (meth)acrylic copolymer (A-1), 25 parts by mass of a urethane acrylate oligomer (available from AGC Inc., LD301, weight-average molecular weight: approximately 10,000, Tg: −63° C.) containing a monofunctional urethane acrylate having a propylene glycol skeleton as a main component as a photocurable compound (B), 3 parts by mass of a mixture of 4-methylbenzophenone and 2,4,6-trimethylbenzophenone (available from IGM Resins B.V, ESACURE TZT) as a photopolymerization initiator (C), 0.3 parts by mass of silane coupling agent (D) (available from Shin-Etsu Silicone Co., Ltd., KBM403), and 200 parts by mass of ethyl acetate as a solvent were uniformly mixed to produce a solution of an adhesive composition.

The solution of the adhesive composition was applied on a release film (available from Mitsubishi Chemical Corporation, silicone-release-treated polyester film, thickness: 100 μm) so that a thickness after drying was 25 μm. After the applying, the coating was placed in a drying apparatus, heated to a temperature of 90° C., and retained for 10 minutes for drying to evaporate the solvent contained in the adhesive composition.

On the surface of the adhesive composition in which the solvent was evaporated, a release film (available from Mitsubishi Chemical Corporation, silicone-release-treated polyester film, thickness: 75 μm) was laminated to form a laminate. The laminate was irradiated with UV by using a high-pressure mercury lamp via the release film so that an integrated light quantity at a wavelength of 365 nm was 500 mJ/cm² to obtain an adhesive sheet (adhesive sheet with a release film).

### Examples 2 to 4 and Comparative Examples 1 to 2

Adhesive sheets were produced in the same manner as in Example 1 except that (meth)acrylic copolymers (A-2) to (A-6) having structural units as shown in the following Table 1 were used instead of the (meth)acrylic copolymer (A-1).

### Comparative Example 3

An adhesive sheet was produced in the same manner as in Example 1 except that a (meth)acrylic copolymer (A-7) having structural units as shown in the following Table 1 was used, and the amount of the photocurable compound (B) was 10 parts by mass.

### Evaluation of Adhesive Sheet

The adhesive sheets obtained in Examples and Comparative Examples were measured and evaluated as follows. The following Table 1 shows the results together with the composition of the adhesive composition used in Examples 1 to 4 and Comparative Examples 1 to 3.

### Gel Fraction

The release film was removed from each of the adhesive sheets produced in Examples and Comparative Examples, and a plurality of the adhesive sheets was laminated to form a laminate with 1.0 mm in thickness. Then, the laminate was punched to a cylinder with 8 mm in diameter to form a sample, and this sample was wrapped with a 200-mesh SUS metal net, and immersed in ethyl acetate adjusted to 23° C. for 72 hours. Thereafter, the sample was dried at 75° C. for 4.5 hours, masses of the adhesive before and after the immersion in ethyl acetate were each measured, and a difference between the masses was regarded as a mass of an insoluble adhesive remained in the metal net. A mass percentage of the insoluble adhesive remained in the metal net relative to the mass of the adhesive before the immersion in ethyl acetate was calculated as a gel fraction.

### Glass Transition Temperature (Tg) and Storage Elastic Modulus (G′)

The release film was removed from each of the adhesive sheets produced in Examples and Comparative Examples, and a plurality of the adhesive sheets was laminated to form a laminate with 1.0 mm in thickness.

The obtained laminate of the adhesive sheets was punched to a cylinder with 8 mm in diameter (1.0 mm in height) to form a sample.

Temperature dispersion of dynamic viscoelasticity of the sample was measured under the following measurement conditions by using a viscoelasticity measurement apparatus (available from T. A. Instruments, DHR 2).

From the obtained temperature dispersion data of the dynamic viscoelasticity, a peak temperature of a loss tangent (tan δ) was read as the glass transition temperature (Tg).

In addition, storage shearing elastic moduli (G′) at 20° C. and 25° C. were read.

### (Measurement Conditions)

Measurement tool: Φ 8 mm parallel plate
Strain: 0.1%
Frequency: 1 Hz
Measurement temperature: −60 to 100° C.
Temperature raising rate: 5° C./min.

### Adhesive Force

One of the release films was removed from each of the adhesive sheets produced in Examples and Comparative Examples. On the adhesive surface of the adhesive sheet, a polyethylene terephthalate film (available from Mitsubishi Chemical Corporation, S100, thickness: 50 μm) as a lining film was rolling-laminated with a hand roller. This laminate was cut to a strip shape with 10 mm in width×150 mm in length, the remained release film was peeled, the exposed adhesive surface was rolling-laminated by using a hand roller onto a transparent polyimide film (main component: transparent polyimide, “C50” available from Kolon Industries, Inc., hereinafter referred to as “CPI film”) laminated onto a glass plate in advance to produce a laminate composed of the CPI film/the adhesive sheet/the lining film.

The laminate was left to stand under a room temperature (23° C., 50% RH) environment for five days to be aged, and then the lining film was peeled while tensing with an angle of 180° formed with the CPI film at a peeling rate of 300 mm/min., and a tensile strength was measured with a load cell to measure a180°—peeling strength (N/cm) of the adhesive sheet relative to the CPI film, which was specified as the adhesive force (A).

By the same procedure as the method for producing the sample of the adhesive force measurement, a laminate composed of the CPI film/the adhesive sheet/the lining film was produced.

At both ends in a length direction of the adhesive sheet of the laminate, a mixed liquid of Oleic acid:Squalene=1:1 (referred to as “artificial sebum liquid”) was dropped at 1 μL/cm, and the adhesive sheet was left to stand under a room temperature (23° C. and 50% RH) environment for five days to be aged. Thereafter, the lining film was peeled while tensing with an angle of 180° formed with the CPI film at a peeling rate of 300 mm/min., and a tensile strength was measured with a load cell to measure a180°—peeling strength (N/cm) of the adhesive sheet relative to the CPI film, which was specified as the adhesive force (B).

### Oil-Resistant Adhesion Rate

An oil-resistant adhesion rate (X) was determined from the following formula by using the values of the adhesive force (A) and the adhesive force (B) measured in the adhesive force tests.

$$\text{Oil-resistant} adhesion rate ( X ) [ \% ] = ( B / A ) \times 100$$

### Recovering Rate (Constant Stress)

The release film was removed from each of the adhesive sheets produced in Examples and Comparative Examples, and a plurality of the adhesive sheets was laminated to form a laminate with 1.0 mm in thickness.

The obtained laminate of the adhesive sheets was punched to a cylinder with 8 mm in diameter (1.0 mm in height) to form a sample.

By using a viscoelasticity measurement apparatus (available from T. A. Instruments, DHR 2), a recovering rate of the sample was measured by applying a stress of 20 kPa at 25° C. for 10 minutes and reading a residual strain value from a maximum strain value (εₘₐₓ) after 10 minutes from removing the stress.

The recovering rate can be determined by calculation with the following formula.

$$Recovering Rate ( \% ) = [ ( {ε}_{max} - Residental strain value ) / {ε}_{max} ] \times 100$$

### Bending Durability

The release film was removed from each of the adhesive sheets produced in Examples and Comparative Examples, and a polyethylene terephthalate film (available from Mitsubishi Chemical Corporation, S100, thickness: 50 μm) and a CPI film (main component: transparent polyimide, available from Kolon Industries, Inc., C50, thickness: 50 μm) were laminated with a hand roller to obtain a laminate sheet (sample) for bending durability.

The laminated sheet (sample) was each subjected to a U-shape bending cycle evaluation by using a durable system in a thermostatic and humidistatic chamber and using a face-shape unloaded U-shape expansion tester (available from Yuasa System Co., Ltd.) with setting of a curvature radius R=3 mm at 60 rpm (1 Hz) under a condition at 25° C. or 20° C. The evaluation was performed with each 40,000 cycles. The evaluation was performed with the following evaluation criteria.

Very Good: None of delamination, breakage, buckling, or floating occurred at a bending portion.

Poor Any of delamination, breakage, buckling, or floating occurred at a bending portion.

TABLE 1

| | | | Ex. 1 | Ex. 2 | Ex. 3 | Ex. 4 | Comp. Ex. 1 | Comp. Ex. 2 | Comp. Ex. 3 |
|---|---|---|---|---|---|---|---|---|---|
| | | | A-1 | A-2 | A-3 | A-4 | A-5 | A-6 | A-7 |
| (Meth)acrylic | Alkyl | BA | 40 | 30.1 | 39.9 | 49.7 | 1 | 15.2 | 35 |
| copolymer (A) | (meth)acrylate (a1) | | | | | | | | |
| | (Meth)acrylate (a2) | 2-EHA | 40 | 39.9 | 30.1 | 20.3 | 67 | 64.8 | 35 |
| | Polar-group- | HEA | 17.5 | 30 | 30 | 30 | 14 | 17.5 | 20 |
| | containing | HBA | — | — | — | — | 4 | — | — |
| | monomer (a3) | | | | | | | | |
| | Other monomers | MA | 2.5 | — | — | — | 5 | 2.5 | 5 |
| | | EA | — | — | — | — | 10 | — | — |
| | | EMA | — | — | — | — | — | — | 5 |
| | W(a2)/W(a1) | — | 1.00 | 1.33 | 0.75 | 0.41 | — | 4.26 | 1.00 |
| | Weight-average | — | 1,060,000 | 950,000 | 1,000,000 | 1,200,000 | 700,000 | 1,040,000 | 900,000 |
| | molecular weight | | | | | | | | |
| Adhesive | Gel fraction | % | 72 | 66 | 67 | 71 | 67 | 74 | 74 |
| sheet | Glass transition | ° C. | −40 | −39 | −37 | −32 | −37 | −40 | −27 |
| | temperature (Tg) | | | | | | | | |
| | G′ (−20° C.) | kPa | 214 | 232 | 257 | 328 | 256 | 192 | 833 |
| | G′ (25° C.) | kPa | 54 | 44 | 47 | 57 | 32 | 43 | 77 |
| | Adhesive force A | N/cm | 6.3 | 7.0 | 6.6 | 6.4 | 12.8 | 8.0 | 7.5 |
| | Adhesive force B | N/cm | 5.4 | 6.3 | 6.3 | 6.1 | 10.1 | 6.6 | 6.3 |
| | Oil-resistant | % | 86 | 90 | 95 | 95 | 79 | 83 | 85 |
| | adhesion rate (X) | | | | | | | | |
| | Maximum strain value | % | 224 | 329 | 294 | 203 | 393 | 278 | 176 |
| | Recovering rate | % | 88 | 85 | 81 | 72 | 90 | 90 | 70 |
| | Bending durability | — | Very Good | Very Good | Very Good | Very Good | Very Good | Very Good | Very Good |
| | (25° C.) | | | | | | | | |
| | Bending durability | — | Very Good | Very Good | Very Good | Very Good | Very Good | Very Good | Poor |
| | (−20° C.) | | | | | | | | |

BA: n-butyl acrylate, 2-EA: 2-ethylhexyl acrylate, HEA: hydroxyethyl acrylate HBA hydroxybutyl acrylate, MA: methyl acrylate, EA: ethyl acrylate, EMA: ethyl methacrylate

From the Table 1, the adhesive sheets of Examples 1 to 4 had excellent flexibleness and oil resistance. Meanwhile, the adhesive sheet of Comparative Example 1, which did not contain the alkyl (meth)acrylate (a1), and the adhesive sheet of Comparative Example 2, which had an excessive proportion of the structural unit derived from the alkyl (meth)acrylate (a1), had excellent flexibleness but poor oil resistance.

The adhesive sheet of Comparative Example 3 had excellent oil resistance but exhibited the high storage shearing elastic modulus (G′) at −20° C., which had poor bending durability at low temperature.

The specific embodiments of the present disclosure have been demonstrated in the above Examples, but the above Examples are merely examples and should not be limitedly interpreted. Various modifications obvious to a person skilled in the art are intended to be all included within the scope of the present disclosure.

### INDUSTRIAL APPLICABILITY

The adhesive sheet of the present disclosure, specifically the adhesive sheet for a flexible image display device, can yield the laminate for a surface-protective film having a surface-protective function, flexibleness such as reliability against bending (bending durability) and excellent oil resistance while the adhesive sheet adheres to an image display device for use. Therefore, the obtained laminate for a surface-protective film is useful as the laminate for a surface-protective film of various flexible image display devices such as bendable, foldable, rollable, and stretchable devices, and particularly suitable as the laminate for a surface-protective film of a foldable image display device causing repeated folding.

1. An adhesive sheet, comprising an adhesive layer formed from an adhesive composition containing: a (meth)acrylic copolymer (A); a photocurable compound (B); and a photopolymerization initiator (C), wherein
the (meth)acrylic copolymer (A) has: a structural unit derived from an alkyl (meth)acrylate (a1) having a linear and/or branched alkyl group having 3 to 6 carbon atoms; and a structural unit derived from a (meth)acrylate (a2) in which a homopolymer thereof has a glass transition temperature lower than that of the alkyl (meth)acrylate (a1),
the structural unit derived from the alkyl (meth)acrylate (a1) is contained by not less than 20 mass % and not greater than 60 mass % relative to 100 mass % of all structural units to constitute the (meth)acrylic copolymer (A),
a content mass ratio (W(a2)/W(a1)) of the structural unit derived from the (meth)acrylate (a2) relative to the structural unit derived from the alkyl (meth)acrylate (a1) is 0.3 to 3.0, and
the adhesive sheet has a storage shearing elastic modulus (G′) at −20° C. of not greater than 800 kPa.

2. The adhesive sheet according to claim 1, wherein the (meth)acrylic copolymer (A) further has a structural unit derived from a polar-group-containing monomer (a3).

3. The adhesive sheet according to claim 1, wherein the (meth)acrylic copolymer (A) has a weight-average molecular weight of 600,000 to 1,500,000.

4. The adhesive sheet according to claim 1, wherein the photocurable compound (B) comprises a (meth)acrylate having a polyalkylene oxide skeleton.

5. The adhesive sheet according to claim 1, wherein the adhesive composition further comprises a silane coupling agent (D).

6. The adhesive sheet according to claim 1, wherein the adhesive sheet has a storage shearing elastic modulus (G′) at −20° C. of not greater than 500 kPa.

7. The adhesive sheet according to claim 1, wherein the adhesive sheet has a gel fraction of 30 to 95 mass %.

8. The adhesive sheet according to claim 1, wherein the adhesive sheet has an oil-resistant adhesion rate (X) determined by the following formula of not less than 84%,
$$X ( \% ) = ( B / A ) \times 100$$
wherein A represents an adhesive force relative to a surface of a polyimide film where the adhesive sheet is cut to 10 mm in width×150 mm in length and adheres to the polyimide film, and peeled at 23° C., 50% RH, a peeling angle of 180°, and a peeling speed of 300 mm/min., and
B represents an adhesive force relative to a surface of a polyimide film where the adhesive sheet is cut to 10 mm in width×150 mm in length and adheres to the polyimide film, a mixed liquid of Oleic acid:Squalene=1:1 (an artificial sebum liquid) is dropped at 1 μL/cm at both ends in a length direction of the adhesive sheet, the adhesive sheet is stored at 23° C. and 50% RH for five days, and then peeled at a peeling angle of 180° and a peeling speed of 300 mm/min.

9. The adhesive sheet according to claim 1, wherein the adhesive sheet is transparent.

10. The adhesive sheet according to claim 1, wherein the adhesive sheet has a total light transmittance of not less than 80% and a haze of not greater than 5%.

11. The adhesive sheet according to claim 1, wherein the adhesive sheet is used for a constituent member of a flexible image display device.

12. An adhesive sheet with a release film, wherein the adhesive sheet has a configuration in which the adhesive sheet according to claim 1 and a release film are laminated.

13. A flexible image display device, comprising:
the adhesive sheet according to claim 1.

14. The flexible image display device according to claim 13, further comprising any one member selected from a polyethylene terephthalate film, a polyimide film, an aramid film, and a glass plate.

15. A flexible image display device comprising:
the adhesive sheet with a released film according to claim 12.

16. The flexible image display device according to claim 15, further comprising any one member selected from a polyethylene terephthalate film, a polyimide film, an aramid film, and a glass plate.
